(19) United States
(12) Patent Application Publication
(10) Pub. No.: US 2025/0077885 A1
(43) Pub. Date: Mar. 6, 2025

(54) SEARCH APPARATUS, SEARCH METHOD, AND SEMICONDUCTOR DEVICE MANUFACTURING SYSTEM

(71) Applicant: Hitachi High-Tech Corporation, Minato-ku, Tokyo (JP)

(72) Inventors: Takeshi NAKAYAMA, Tokyo (JP); Hyakka NAKADA, Tokyo (JP); Takeshi OHMORI, Tokyo (JP)

(21) Appl. No.: 18/279,478

(22) PCT Filed: May 20, 2022
(86) PCT No.: PCT/JP2022/020930

§ 371 Date: Aug. 30, 2023

(51) Int. Cl. G06N 3/096; G05B 17/02

(52) U.S. Cl. CPC G06N 3/096; G05B 17/02

(57) ABSTRACT

In order to enable a user to utilize optimum reference processing data for searching for a target processing condition from a large number of stored reference processing data without requiring special knowledge of machine learning, a search apparatus that searches for a manufacturing condition corresponding to a desired processing result of a semiconductor manufacturing apparatus by predicting the manufacturing condition corresponding to the desired processing result using a learning model is configured to generate a learning model by transfer learning using first data and second data, and regenerate, when the generated learning model does not satisfy a predetermined determination criterion, a learning model by transfer learning using the first data and the added second data.

### TECHNICAL FIELD

The present invention relates to a search apparatus, a search method, and a semiconductor device manufacturing system that search for a manufacturing condition for realizing a desired processing result.

### BACKGROUND ART

In semiconductor manufacturing, an appropriate processing condition needs to be set in order to obtain a desired processing result. With a continuous increase in miniaturization and processing control parameters of a semiconductor device, it is considered that a processing condition for obtaining a desired processing result (machine difference prevention and high accuracy) is derived from machine learning in the future. Here, the processing condition includes items of at least one or more control parameters of a processing device.

In recent years, many new items have been added to the processing condition by the expansion of a control range of the processing device due to the introduction of new materials and the complication of a device structure. In order to extract a performance of the processing device sufficiently, it is necessary to optimize the processing condition. For this reason, attention has been paid to a method for deriving, by machine learning, a processing condition for realizing a good processing result requested by a process developer. Here, the processing result includes at least one or more items indicating a shape, properties, and the like of a sample subjected to processing. Hereinafter, the good processing result will be referred to as a “target processing result”.

The target processing result will be described using an example of an etching process for an etching target material on a silicon (Si) wafer 11. FIG. 1 shows the entire wafer, and cross-sectional views of two places in the vicinity of a center 12 and in the vicinity of an edge 13 of a surface of the Si wafer 11 after the etching process. By removing an etching target material 14 formed on the surface of the Si wafer 11 by etching and measuring a difference in height of a pre-etching surface 16 indicated by a broken line, an etching amount 15 in the etched portion can be estimated.

An etching rate and in-plane uniformity of the etching rate can be calculated from in-plane distribution data of the etching amount 15 and the time required for etching. Assuming that the etching rate is an item of the processing result, the target processing result is defined as a predetermined value or a predetermined value range such as “an etching rate of 50 nm/min” and “an etching amount of 20 nm within in-plane variation of 5%”. The processing condition for realizing such a target processing result is referred to as a “target processing condition”.

A method for deriving the target processing condition by machine learning is generally performed in the following procedure. First, the target processing result is set. Meanwhile, a plurality of basic processing conditions are determined, the sample is subjected to processing based on the basic processing conditions, processing data including the basic processing conditions and processing results thereof is acquired, and an initial processing database is constructed. A model describing a correlation between each basic processing condition and a processing result of the basic processing condition is estimated by machine learning based on the initial processing database. Hereinafter, with respect to such a model, when a processing condition is an input x and a processing result thereof is an output y, the model becomes a model describing an input and output relation y=f(x), and thus this model is referred to as an input and output model. Based on the estimated input and output model, a processing condition (referred to as a “prediction processing condition”) that satisfies the target processing result is predicted.

Subsequently, a verification experiment is performed using the obtained prediction processing condition. That is, the processing based on the prediction processing condition is executed, and it is determined whether the obtained processing result is the target processing result. When the target processing result is obtained, the verification experiment is ended using the prediction processing condition as the target processing condition. On the other hand, if the target processing result is not obtained, the input and output model is updated by adding the processing data obtained in the verification experiment to the database, and the prediction of the processing condition and the verification experiment are repeated until the target processing result is obtained.

In a method for deriving such a target processing condition, accuracy of the input and output model used to predict the target processing condition is important. FIG. 2 is a graph showing a correlation (an input and output relation) between the processing condition and the processing result. Here, a broken line 21 indicates a true input and output relation, while a solid line 22 and a dashed line 23 indicate input and output relations represented by an input and output model A and an input and output model B, respectively. The accuracy of the input and output model can be evaluated as a degree of similarity between the input and output relation of the input and output model and the true input and output relation indicated by the broken line. In this case, the input and output relation of the input and output model A (the solid line 22) is similar to the true input and output relation (the broken line 21), and the accuracy of the input and output model A is high. On the other hand, the input and output relation of the input and output model B (the dashed line 23) deviates from the true input and output relation (the broken line 21), and the accuracy of the input and output model B is low.

The processing result according to the prediction processing condition obtained based on the input and output model having low accuracy is highly likely to be a result deviating from the target processing result. Therefore, the number of verification experiments is increased until the target processing condition is obtained. Accordingly, a process development period and a process development cost such as an experimental cost and a labor cost increase. In order to avoid such a situation, it is necessary to improve the accuracy of the input and output model.

In order to improve the accuracy of the input and output model, a method for constructing a large-scale initial processing database in advance is considered. However, in this method, it is necessary to repeat the processing many times in order to construct the initial processing database, and there is no fundamental solution to reduce the process development period and the process development cost.

As a method for improving accuracy of an input and output model while reducing the number of acquired processing data for constructing an initial processing database, there is a technique of utilizing processing data acquired by a process different from a process (referred to as a “target process”) for deriving a processing condition. Specifically, an input and output model (referred to as “a reference input and output model”) describing an input and output relation in a reference process is estimated based on a database (referred to as a “reference processing database”) of processing data (referred to as “reference processing data”) acquired in a process (referred to as a “reference process”) different from a target process, and the estimated reference input and output model is referred to for prediction in the target process.

PTL 1 discloses “a computer for determining a control parameter of processing to be performed on a sample, the computer including: a memory unit that stores a first model indicating a correlation between a first processing output obtained by measuring a first sample used for manufacturing, on which the processing is performed and a second processing output obtained by measuring a second sample that is easier to measure than the first sample and on which the processing is performed, and a second model indicating a correlation between a control parameter of the processing performed on the second sample and the second processing output; and an analysis unit that calculates a target control parameter of the processing performed on the first sample based on a target processing output as the target first processing output, the first model, and the second model”, so that “optimal control parameters can be calculated while reducing a cost of process development”. PTL 1 describes as an example that a “qualitative real sample-substitute sample relation model in which A is larger as B is larger” is used as the first model, where A is a variable of the processing output of a substitute sample, which is the second sample, and B is a variable of the processing output of an actual sample, which is the first sample.

PTL 2 discloses “a processing condition search apparatus that searches for a processing condition in a target process, the processing condition search apparatus including: a target processing result setting unit that sets a target processing result in the target process; a processing database that stores target processing data, which is a combination of a processing condition and a processing result in the target process; a learning database including a reference processing database that stores reference processing data, which is a combination of a processing condition and a processing result in a reference process; a supervised learning execution unit that estimates an input and output model of the target process, which is an input and output model between a target explanatory variable and a target objective variable, the processing condition of the target processing data being defined as the target explanatory variable and the processing result being defined as the target objective variable, using the target processing data; a transfer learning execution unit that estimates an input and output model of the target process using the target processing data and a reference input and output model between a reference explanatory variable and a reference objective variable, the processing condition of the reference processing data being defined as the reference explanatory variable and the processing result being defined as the reference objective variable; a transferability determination unit that determines whether the supervised learning execution unit or the transfer learning execution unit is used to estimate the input and output model of the target process; and a processing condition prediction unit that predicts the processing condition for realizing the target processing result, using the input and output model of the target process”, so that “target processing condition is searched for while reducing a process development period and a process development cost”.

PTL 2 discloses as an example that a combination of simulation results and simulation conditions that are obtained by simulation of the target process is used as the reference processing database, instead of data obtained by actually performing processing by the processing device as the reference processing data.

### CITATION LIST

### Patent Literature

PTL 1: JP2019-047100A
PTL 2: JP2021-182182A

### SUMMARY OF INVENTION

### Technical Problem

In the method for determining the control parameter of the processing described in PTL 1, the processing data of the second sample is utilized as the reference processing data to estimate the reference input and output model. The processing condition for the first sample is determined by referring to the reference input and output model. As described above, it is considered that some conditions are required to be satisfied in order to effectively predict the processing in the target process with reference to the reference input and output model.

FIG. 3A is a graph showing an input and output relation (a solid line 30) of an input and output model estimated based on processing data including processing results acquired by setting a plurality of basic processing conditions for the target process and a true input and output relation (a broken line 20) of the target process. In this example, there are a few set basic processing conditions (black dots represent processing data, and the same applies to FIGS. 3B and 3C), and an accuracy of the input and output model is low.

FIG. 3B is a graph showing an input and output relation (a solid line 31) of a reference input and output model estimated based on reference processing data stored in the reference processing database for the reference process and a true input and output relation (a broken line 21) of the reference process. In this example, since the reference processing database is large-scale, the accuracy of the reference input and output model is high.

FIG. 3C is a graph showing an input and output relation (a solid line 32) of an input and output model estimated by performing transfer learning referring to the reference input and output model shown in FIG. 3B and a true input and output relation (a broken line 20) of the target process. The processing data of the target process used for the transfer learning is the same as that in FIG. 3A, but since the true input and output relation of the target process (the broken line 20) and the true input and output relation of the reference process (the broken line 21) are similar to each other, the accuracy of the input and output model estimated by performing the transfer learning is higher than the accuracy of the input and output model shown in FIG. 3A.

Here, the true input and output relations f and g being similar to each other includes not only a case where the true input and output relations f and g substantially match each other but also a case where the true input and output relations f and g substantially match each other except for a difference in constant or coefficient. That is, f≈g and f≈ag+b are satisfied. For example, in a case where both the target process and the reference process are the etching processing for the same sample, and only the processing time is different, that is, 10 seconds and 100 seconds, respectively, even when there is a difference of approximately 10 times in the processing result, basic function characteristics are common. That is, f≈10 g is satisfied for the true input and output relation, and an application effect of the transfer learning is expected.

As described above, a method for utilizing the reference processing data of the reference process (transfer learning) is effective when, for example, the true input and output relation between the target process and the reference process is similar or the reference input and output model has higher accuracy than that of the input and output model estimated only from the target processing data, but the method is not necessarily effective if these conditions are not satisfied.

In a semiconductor process, since there are various types of samples, processing devices, and processing processes, there are generally many candidates for the reference processing data. However, depending on the selection of the reference processing data, the accuracy of the input and output model may not be improved as expected.

For example, even when the target process and the reference process are the same etching process and an item of the processing result is an etching amount in any process, in a case where there are different materials for a film to be etched of a sample to be processed, there is a significant difference in characteristics of an etching rate with respect to the processing condition. Therefore, the true input and output relations are not similar in the first place.

Further, even when reference processing data having a similar true input and output relation is selected to estimate the reference input and output model, in a case where the number of pieces of reference processing data is significantly small and a reference input and output model having sufficiently high accuracy cannot be obtained, it may not be possible to obtain an improvement in accuracy by referring to the reference input and output model.

When such inappropriate reference processing data is utilized, the accuracy of the input and output model to be predicted cannot be expected to be improved, and the process development period and the process development cost may increase.

In general, in machine learning, since a model performs learning based on known input data and output data, if a model that has finished learning once is reused by transfer learning or the like, even if the explanatory variables of the input data to be input to the model are different from those input at the time of learning, it is necessary to input the same explanatory variables. For example, when there is a learned model that predicts the “etching amount” based on three input conditions of “temperature”, “pressure”, and “processing time”, the “etching amount” cannot be predicted by inputting “power” to the model. It is not possible to provide data in which “temperature” is omitted, and it is necessary to input some value.

In PTL 2, the transfer learning execution unit performs learning using the reference input and output model and the target processing data. In this case, basically, it is considered that the input of the reference input and output model and the explanatory variable of the target processing data correspond to each other in many cases, but in the transfer learning when “a combination of simulation results and simulation conditions that are obtained by simulation of the target process is used as the reference processing database, instead of data obtained by actually performing processing by the processing device as the reference processing data”, the input of the reference input and output model and the explanatory variable of the target processing data cannot always be matched.

For example, in actual processing conditions, “temperature”, “pressure”, and “processing time” are input as experimental conditions, but there may be a case where the term of the temperature cannot be handled due to a simulation model when the processing condition is simulated by a physical simulator. In addition, there are many cases where handling with a simulator is not easy, such as a case where a response to a pulse having a period of several milliseconds or more is incorporated into simulation for handling time evolution in a time scale of microseconds or less, or a case in where metadata such as a processing date and time is desired to be handled. Further, conversely, there may be a parameter that influences the reference processing data but is not included in the explanatory variable of the target processing data, such as a calculation condition used for the simulation.

A difference in the input data format is the same not only in the case where the target processing data is an actual processing result and the reference processing data is a simulation result as described above, but also in the case where the target processing data is the simulation result and the reference processing data is the actual processing result. Furthermore, even when both are the actual processing results, it may happen that a parameter that can be handled by one device cannot be handled by the other device due to a slight change in a system state of the processing device.

As described above, when it is desired to perform transfer learning using two pieces of data having different explanatory variables, it is possible to perform preprocessing of data such as deleting an explanatory variable that is not present in one piece of data or inputting a certain value or a predicted value instead, or to change a network structure of a model in a neural network model.

In the former method for deleting an explanatory variable or inputting a constant value or a predicted value, data processing is required, a model is obtained in which the explanatory variable which is deleted or to which the constant value is input can not be considered, and accuracy thereof decreases. In the latter change of the network structure, it is necessary to avoid problems such as over-learning and negative transfer at the same time as the degree of freedom of the method itself, and it is difficult for a user unfamiliar with machine learning to perform the change by himself/herself. It is also difficult to select appropriate data for searching for a target processing condition e number of reference processing databases in order to avoid problems such as over-learning and negative transfer.

In order to solve the above-described problems in the related art, the invention provides a search apparatus, a search method, and a semiconductor device manufacturing system that search for a manufacturing condition for utilizing optimum reference processing data for searching for a target processing condition from a large number of stored reference processing data while continuously and automatically storing reference processing data without requiring special knowledge of machine learning of a user.

### Solution to Problem

In order to solve the above problems, the invention provides a search apparatus that searches for a manufacturing condition corresponding to a desired processing result of a semiconductor manufacturing apparatus by predicting the manufacturing condition corresponding to the desired processing result using a learning model. The search apparatus is configured to generate a learning model by transfer learning using first data and second data, and regenerate, when the generated learning model does not satisfy a predetermined determination criterion, a learning model by transfer learning using the first data and the added second data.

In order to solve the above problems, the invention provides a search method for searching for a manufacturing condition corresponding to a desired processing result of a semiconductor manufacturing apparatus by predicting the manufacturing condition corresponding to the desired processing result using a learning model. The search method includes: a step of generating a learning model by transfer learning using first data and second data; and a step of, when the generated learning model does not satisfy a predetermined determination criterion, regenerating the learning model by transfer learning using the first data and the added second data.

In order to solve the above problems, the invention provides a semiconductor device manufacturing system that includes a platform to which a semiconductor manufacturing apparatus is connected via a network and in which an application for predicting a manufacturing condition corresponding to a desired processing result of the semiconductor manufacturing apparatus using learning model is implemented. The semiconductor device manufacturing system is configured to execute, by the application, a step of generating a learning model by transfer learning using first data and second data, and a step of, when the generated learning model does not satisfy a predetermined determination criterion, regenerating the learning model by transfer learning using the first data and the added second data.

### Advantageous Effects of Invention

According to the invention, a target processing condition can be searched for while reducing a process development period and a process development cost. Even in a period in which actual processing of a target process is not performed, a reference processing data acquisition and automatic execution unit can automatically improve prediction accuracy continuously.

### BRIEF DESCRIPTION OF DRAWINGS

FIG. 1 shows a perspective view of a wafer, and enlarged views of cross sections of a surface in the vicinity of a center of the wafer and a surface in the vicinity of an end of the wafer.

FIG. 2 is a diagram illustrating a background of the invention, and is a graph showing a correlation (input and output relation) between a processing condition and a processing result.

FIG. 3A is a graph showing a relation between a processing condition (input) and a processing result (output) for describing a problem of the invention, and shows an input and output relation of an estimated input and output model and a true input and output relation of a target process when a set basic processing condition is small and accuracy of the input and output model is low.

FIG. 3B is a graph showing a relation between the processing condition (input) and the processing result (output) for describing the problem of the invention, and shows an input and output relation of a reference input and output model estimated based on reference processing data and a true input and output relation of a reference process.

FIG. 3C is a graph showing a relation between the processing condition (input) and the processing result (output) for describing the problem of the invention, and shows an input and output relation of an input and output model estimated by performing transfer learning with reference to a reference input model and a true input and output relation of the target process.

FIG. 4 is a block diagram showing a schematic configuration of a processing condition search system according to Embodiment 1 of the invention.

FIG. 5 is a block diagram showing a concept of a transfer learning model using a neural network according to Embodiment 1 of the invention.

FIG. 6 is a front view of a screen showing an example of a GUI (ROI data selection manager) provided for a user by a model explanation unit according to Embodiment 1 of the invention.

FIG. 7 is a front view of a screen showing an example of a GUI (model optimization end determination criterion setting) provided for the user by a transfer learning model evaluation unit 45 according to Embodiment 1 of the invention.

FIG. 8 is a flowchart illustrating a process from start of an operation to prediction of a target processing condition according to Embodiment 1 of the invention.

FIG. 9 is a flowchart showing a procedure for automatically expanding a reference process database by a computer during a period in which there is no processing condition search operation according to Embodiment 2 of the invention.

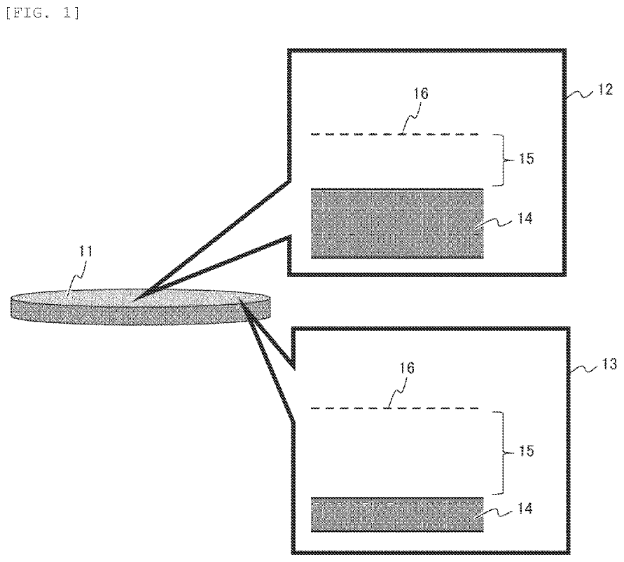

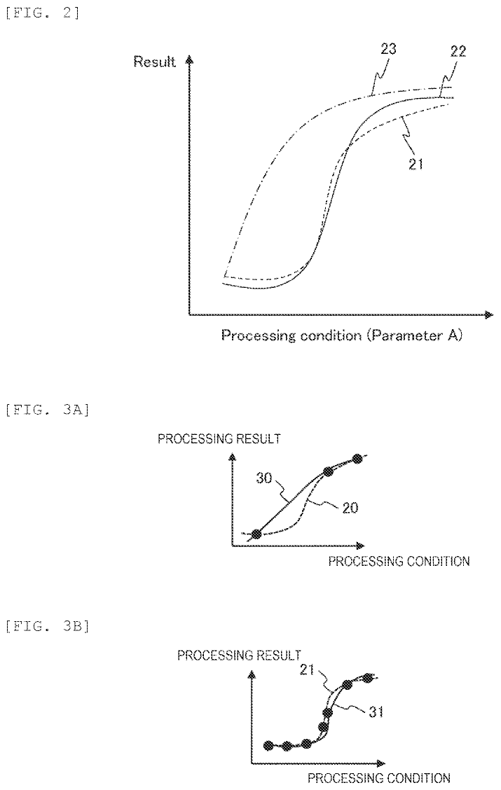

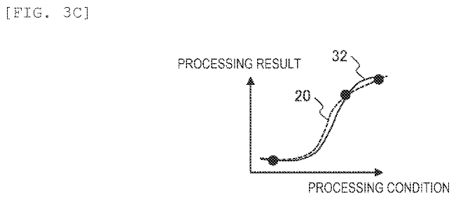

### DESCRIPTION OF EMBODIMENTS

The invention provides a search system that searches for a desired manufacturing condition of a semiconductor manufacturing apparatus by machine learning and in which the desired manufacturing condition of the semiconductor manufacturing apparatus is predicted using a model constructed by transfer learning of data by a physical simulator.

In general, all parameters in actual processing conditions cannot be considered in physical simulation, and in machine learning using a neural net in the related art, data of tasks having different features and labels cannot be learned by a single model, but this problem is solved by a network structure using transfer learning in the invention.

That is, in the invention, features of the model are set in advance by a “model explanation unit” so as not to cause negative transfer, and the model obtained as a result of the transfer learning is evaluated by a “transfer learning model evaluation unit”. As a result of model evaluation, if an evaluation value does not exceed a threshold, simulation data of conditions necessary for improving accuracy of a transfer learning model is automatically generated from an attached computer (“reference process data acquisition and automatic execution unit”), and the transfer learning is performed again.

As a result, a transfer learning model optimum for predicting a target processing result set by a user is normally automatically constructed and updated, and it is possible to shorten and reduce a recipe optimization period for reducing a mechanical difference/component difference by utilizing a large amount of labeled data by simulation, which costs less than actual processing.

Embodiments of the invention will be described below with reference to drawings. However, the invention should not be construed as being limited to the description of the embodiments described below. A person skilled in the art could have easily understood that a specific configuration can be changed without departing from the spirit or gist of the invention. Positions, sizes, shapes, and the like of respective components shown in the drawings and the like in this specification may not represent the actual positions, sizes, shapes, and the like in order to facilitate understanding of the invention. Therefore, the invention is not limited to the positions, the sizes, the shapes, and the like disclosed in the drawings.

### Embodiment 1

In the present embodiment, an example is described in which, in order to be able to search for a target processing condition while reducing a process development period and a process development cost, a processing condition search apparatus that searches for a processing condition in a target process includes: a target processing result setting unit that sets a target processing result in the target process; a target processing database that stores target processing data, which is a combination of a processing condition and a processing result in the target process; a learning database including a reference processing database that stores reference processing data, which is a combination of a processing condition and a processing result in a reference process; a model explanation unit that explains features of a reference input and output model between a reference explanatory variable and a reference objective variable, the processing condition being defined as the reference explanatory variable and the processing result being defined as the reference objective variable, using the reference processing data; a transfer learning execution unit that estimates an input and output model of the target process using a target explanatory variable, a target objective variable, and the reference input and output model, the processing condition of the target processing data being defined as the target explanatory variable and the processing result being defined as the target objective variable, using the target processing data; a transfer learning model evaluation unit that evaluates a transfer learning model, which is a target process input and output model estimated by the transfer learning execution unit; a reference processing data acquisition and automatic execution unit that adds new reference processing data to the reference processing database based on the evaluation of the transfer learning model evaluation unit; and a processing condition prediction unit that predicts a processing condition for realizing a target processing result using the transfer learning model.

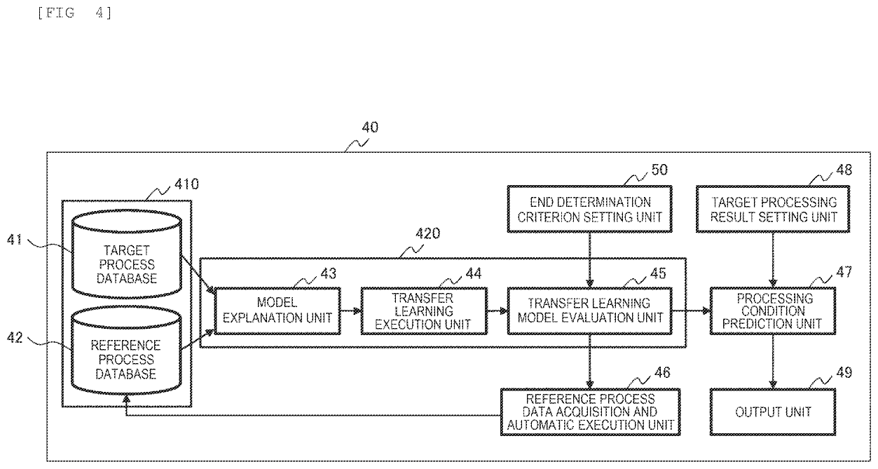

FIG. 4 is a block diagram showing a configuration example of a processing condition search system 40 according to Embodiment 1.

The processing condition search system 40 includes a database unit 410 that stores data of a target process and data of a reference process, a transfer learning execution and evaluation unit 420 that performs transfer learning using the data stored in the database unit 410 and evaluates a created learning model, a reference process data acquisition and automatic execution unit 46 that acquires reference process data when the transfer learning model evaluated by the transfer learning execution and evaluation unit 420 does not clear a target, a processing condition prediction unit 47, a target processing result setting unit 48, and an output unit 49.

The database unit 410 includes a target process database 41 and a reference process database 42, and the transfer learning execution and evaluation unit 420 includes a model explanation unit 43, a transfer learning execution unit 44, and a transfer learning model evaluation unit 45. Components are connected to each other directly or via a network.

The target process database 41 stores target processing result data, which is a combination of past processing conditions Xp and processing results Yp in a target processing device. Here, a type and content of the processing performed by the processing device are not limited. Examples of the processing device include a lithography device, a film forming device, a pattern processing device, an ion implantation device, a heating device, and a cleaning device.

Examples of the lithography device include an exposure device, an electron beam lithography device, and an X-ray lithography device. Examples of the film forming device include CVD, PVD, a vapor deposition device, a sputtering device, and a thermal oxidation device. Examples of the pattern processing device include a wet etching device, a dry etching device, an electron beam processing device, and a laser processing device. Examples of the ion implantation device include a plasma doping device and an ion beam doping device. Examples of the heating device include a resistance heating device, a lamp heating device, and a laser heating device. Examples of the cleaning device include a liquid cleaning device and an ultrasonic cleaning device.

In Embodiment 1, a “dry etching device” is described as a processing device, values actually performed corresponding to items “temperature”, “pressure”, “flow rate of gas A”, “flow rate of gas B”, “power”, and “processing time” are described as processing conditions, and an “etching amount” is described as a processing result. The items “temperature”, “pressure”, “flow rate of gas A”, “flow rate of gas B”, “input power”, and “processing time” of the processing conditions Xp are referred to as explanatory variables, and the item “etching amount” of the processing results Yp is referred to as an objective variable.

The reference process database 42 stores reference processing result data, which is a combination of simulation conditions Xs and simulation results Ys in simulation for simulating the target process. Here, a type and content of the simulation are not limited. In Embodiment 1, the description is made on the assumption that “electromagnetic field calculation in plasma using a finite element method” is described as the content of the simulation, the values actually performed corresponding to the items “pressure”, “flow rate of gas A”, “flow rate of gas B”, and “power” are described as simulation conditions, and the items “ion amount of A” and “ion amount of B” are described as simulation results, but the reference process database includes more explanatory variables and objective variables.

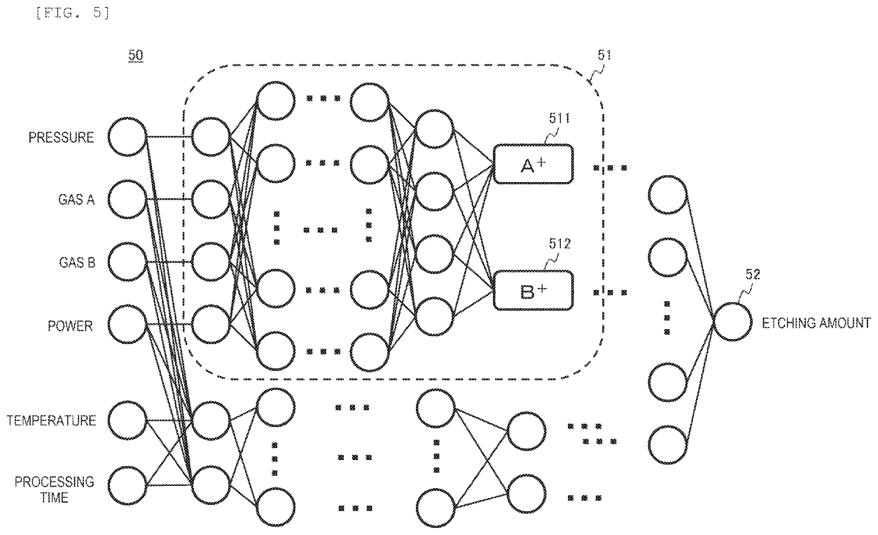

As described above, the explanatory variables and the numbers of the explanatory variables of the processing conditions Xp of the target process database 41 and the simulation conditions Xs of the reference process database 42 do not need to match each other, and the objective variables and the numbers of the objective variables of the processing results Yp and the simulation results Ys do not need to match each other. In Embodiment 1, the items of the explanatory variables of Xs are a subset of the explanatory variables of Xp. FIG. 5 shows a transfer learning model 50 using a typical neural network in such a case.

In the example shown in FIG. 5, a reference model 51 surrounded by broken lines is included in the transfer learning model 50, and in the learning of the transfer learning model 50, a weight of a portion of the reference model 51 may be fixed or may be used as an initial value for performing relearning (fine tuning).

In FIG. 5, although an output unit of the reference model 51 is an ion amount of A (A⁺) 511 and an ion amount of B (B⁺) 512, it is possible to freely change a type and the number based on the knowledge of the user who handles the processing device in accordance with an objective variable (here, the “etching amount”) 52 of the target process of which the user wants finally increase prediction accuracy.

For example, in this target process, the user assumes a phenomenon in which “A ions and B ions are generated from the gas A and the gas B using power, and these ions etch a wafer”. Therefore, it is considered that the “etching amount” can be predicted with high accuracy by setting the “ion amount of A” and the “ion amount of B” to the output.

In Embodiment 1, since the reference process data is based on the simulation, it is possible to relatively freely assign a value of the explanatory variable without worrying about constraint, an interlock, a cost condition, and the like of a safety device (for example, a high voltage condition that exceeds a breakdown voltage performance of the device or a low-temperature condition due to a cooling function that ignores the cost). Therefore, the reference process database 42 may include a large number of data comprehensively assigning various parameters.

Although it is also possible to construct a transfer learning model using all the reference process data stored in the reference process database 42, it is considered here that a model having higher accuracy and more specific to the target process requested by the user is used. A data group used for the transfer learning is selected based on an appropriate determination from reference process data groups stored in the reference process database 42, so that a transfer learning model with higher prediction accuracy can be constructed.

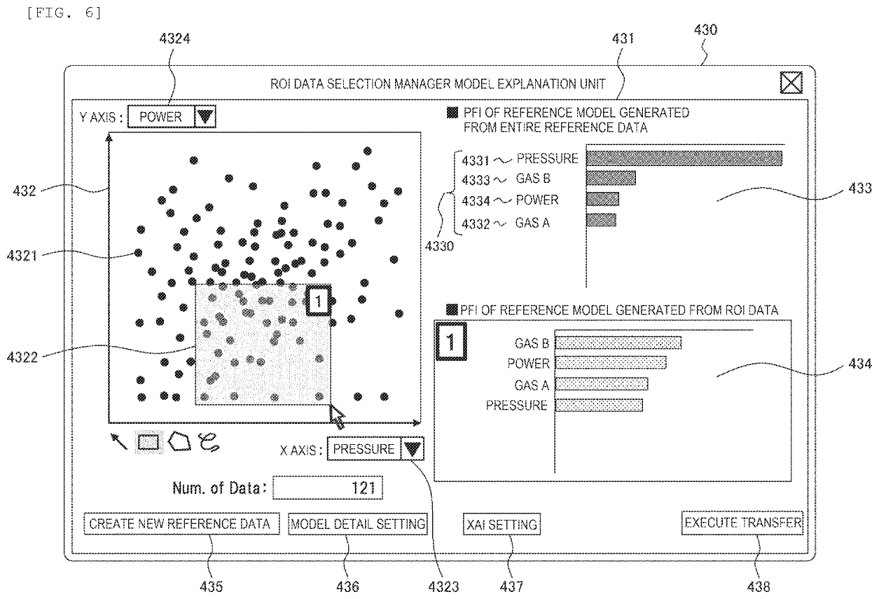

FIG. 6 is an example of a GUI (ROI data selection manager) 430 provided for the user by the model explanation unit 43. The GUI 430 is displayed on a screen of the output unit 49. For the reference model created from the reference process data stored in the reference process database 42, the model explanation unit 43 can display features of the model on the GUI 430 using an explainable AI (XAI) method that is selected and set by an XAI setting button 437. Although various methods are present as the XAI, here, PFI values of the reference model using a permutation feature importance (PFI) method are calculated, and the values are displayed in ranking on the GUI 430 by bars 433 and 434. In Embodiment 1, since four parameters, that is, “pressure” 4331, “flow rate of gas A” 4332, “flow rate of gas B” 4333, and “power” 4334 are present in the simulation conditions Xs 4330 of the reference process database 42, PFI ranking display of four elements is performed.

The PFI value is expressed as a ratio of how much each explanatory variable alone contributes to the prediction accuracy of the model. This PFI value is greatly influenced by a network structure of the model, in particular, a data group used for learning.

A data set to be used for learning the reference model to be used for transfer learning is selected by any method such as clicking a “create new reference data” button 435 to create new reference data or clicking a “model detail setting” button 436 to set detailed conditions of model selection while viewing a position and variance of a data point 4321 in a data space in a graph 432 on a left side of an “ROI data selection manager model explanation unit” window 431 in FIG. 6.

A graph 432 in FIG. 6 shows a state in which 121 reference model learning data sets 4322 are selected by ROI rectangle selection in the two-dimensional data distribution relating to “power” 4324 and “pressure” 4323. Although the calculation of the PFI value obtained here takes some time depending on the data amount or the like, the user can continue the work by performing a second ROI selection to be performed next while waiting for the calculation.

With the GUI 430 shown in FIG. 6, the user can optimize the reference model used for transfer learning in the transfer learning execution unit 44 while confirming “what kind of data is selected and what model is obtained by transfer learning”, but the GUI 430 is not necessarily displayed to allow the user to make a determination as described above, a certain level of accuracy can be achieved even when the transfer learning is automatically performed using all the data stored in the reference process database 42, and thus the GUI 430 is not essential.

When a determination criterion is set in advance based on, for example, the PFI value, it is possible for the model explanation unit 43 to automatically optimize the reference model used for the transfer learning without a user operation.

However, it is necessary to pay attention that the PFI value explained by the model explanation unit 43 in Embodiment 1 is simply “how much each explanatory variable alone contributes to the prediction accuracy of the reference model for predicting the ion amount of A and the ion amount of B”, and is not essential “how much each explanatory variable contributes to the determination of the ion amount of A and the ion amount of B”. It is necessary to pay attention that the user can freely set “the ‘ion amount of A’ and the ‘Ion amount of B’ of the output of the reference model are useful for predicting the “etching amount” (FIG. 5), in other words, it cannot be said with certainty that “the higher the prediction accuracy of the reference model, the higher the prediction accuracy of the target model”. However, when the model explanation unit 43 can be used after paying attention thereto, it is possible to optimize the reference model used for the transfer learning with high accuracy in a short time.

Finally, when the user presses a “transfer execution” button 438 at a lower right part of FIG. 6, the transfer learning by the transfer learning execution unit 44 is executed.

The transfer learning model evaluation unit 45 evaluates the model created by the transfer learning execution unit 44, determines that a cause is in the network structure and the reference process data of the model if the evaluation result does not satisfy a certain criterion, and instructs the reference process data acquisition and automatic execution unit 46 to execute automatic acquisition and addition of the reference process data.

When the automatic acquisition and addition of the reference process data is executed by the reference process data acquisition and automatic execution unit 46 and new reference process data is added to the reference process database 42, the determination is performed again by the transfer learning model evaluation unit 45 via the model explanation unit 43 and the transfer learning execution unit 44, and then the processing is looped until the determination criterion of the transfer learning model evaluation unit 45 is satisfied.

Basically, since the prediction accuracy can be expected to be improved as the reference process data increases, the reference process data acquisition and automatic execution unit 46 may continue to perform calculation under simulation conditions according to an experimental design method (DoE) even when automatic acquisition of data is not instructed to the transfer learning model evaluation unit 45, and continue to store the data.

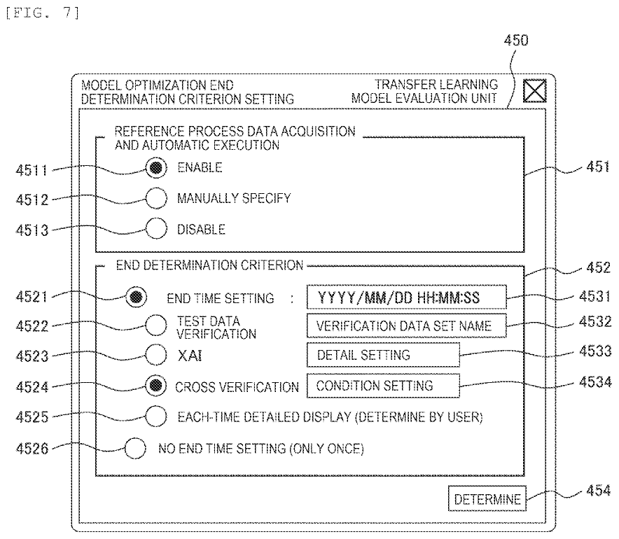

FIG. 7 is an example of a GUI (model optimization end determination criterion setting) 450 provided for the user by the transfer learning model evaluation unit 45. First, the user makes settings related to reference process data acquisition and automatic execution in a reference process data acquisition and automatic execution region 451 of the GUI 450. By selecting any one of an enable button 4511, a manual setting button 4512, and a disable button 4513, it is specified whether a loop for improving the transfer learning model by adding the reference process data using the reference process data acquisition and automatic execution unit 46 is repeated. At this time, it is also possible for the user himself/herself to manually specify conditions instead of automatically leave the simulation conditions according to the experimental design method (DoE) proposed by the reference process data acquisition and automatic execution unit 46.

When the reference process data acquisition and automatic execution is enabled by clicking the enable button 4511, an end determination criterion is set in an end determination criterion setting region 452 of the GUI 450. In a case where an end time is input to an end time setting region 4531 and an “end time setting” button 4521 is clicked to perform the end time setting, even if the set criterion is not satisfied, the reference process data acquisition and automatic execution is repeated until the end time, and a transfer learning model having a best verification result is sent to the processing condition prediction unit 47. When the set criterion is satisfied, the transfer learning model is sent to the processing condition prediction unit 47 without reaching the end time.

An end determination criterion set in the end determination criterion setting region 452 in FIG. 7 will be described.
(1) The expression “test data verification” is a verification method for evaluating a model using test data, which is a combination of the processing conditions Xp and the processing results Yp in several target processes prepared in advance by the user. This test data does not need to be data included in the target process database used for model learning, but needs to be prepared separately, and the test data verification is the most appropriate model evaluation method. For example, in a model for predicting the “etching amount”, a “relative error of an actual etching amount and a predicted etching amount, which is verified by the test data, is less than 5%” is set as a determination condition. By inputting a verification data set name to a verification data set name input region 4532 and clicking a “test verification data” button 4522, the specified test data is selected.
(2) The expression “XAI” is a verification method for making a determination using a value obtained as a result of evaluating a model by the XAI method. For example, “XAI” determines whether conditions are satisfied, such as the PFI value obtained by using the PFI method in the transfer learning model is a fixed value or more and/or less. This is because, for example, the user has chemical and physical knowledge about the target process, and when it is considered that “in the case of this process, an influence of the ‘power’ should be larger than that of the ‘pressure’ in determining the ‘etching amount’”, the “PFI value of the power>the PFI value of the pressure” is set as the determination condition. By setting the verification condition (determination condition) in a detail setting region 4533 and clicking an “XAI” button 4523, the set verification condition (determination condition) is applied, and an evaluation result is determined.
(3) Here, the expression “cross verification” refers to K-division cross verification. The entire learning data used for learning is divided into K pieces, one piece of learning data is taken out as the test data, and the remaining learning data is used as learning data and evaluated in the same manner as in (1). Similarly, the evaluation is performed K times in total so that each of the learning data groups divided into K pieces becomes test data one time once, and an average value of K times of evaluation is obtained, and a determination criterion in the same format as (1) is provided. As compared with (1), accuracy of the evaluation method is slightly inferior due to the reduction in learning data, and an amount of calculation increases and an evaluation time is extended, but the user does not need to prepare test data in advance. When conditions are set in a verification condition setting region 4534 and a “crossing verification” button 4524 is clicked, conditions of the cross verification are set.
(4) The expression “each-time detailed display” is an option that allows the user who is more knowledgeable about a transfer learning method to check not only an XAI evaluation result and a cross verification result of the above transfer learning model, but also a learning curve and a parameter tuning result in detail, and allows the user to make a determination. When a button 4525 is clicked, the screen is switched to a setting screen (not shown), and the user sets the details.

When a “no end time setting (only once)” button 4526 is clicked, the processing of model optimization is executed until the determination criterion of the transfer learning model evaluation unit 45 is satisfied without setting the end time.

Finally, when a “determination” button 454 is clicked, each condition set on the screen of the GUI 450 is sent to the processing condition search system 40 and set as a new condition in the processing condition search system 40.

When using the processing condition search system 40 according to the present embodiment, the user first inputs and specifies what kind of processing result is to be obtained in the target process by the target processing result setting unit 48. For example, the “etching amount” is specified as “40 nm”. Although there is no problem in the operation even when there are a plurality of items, higher accuracy can be expected when the number of items is smaller. The desired processing result may be a range such as “30 nm to 50 nm”.

The target processing result specified by the user is captured by the processing condition prediction unit 47 after the transfer learning model satisfying the criterion of the transfer learning model evaluation unit 45 is sent to the processing condition prediction unit 47. The processing condition prediction unit 47 optimizes, by a root-finding algorithm such as Newton's method, a processing condition for obtaining a prediction processing result that is closest to the target processing result set by the target processing result setting unit 48. The optimized processing condition is provided for the user by means such as GUI display or csv file storage on the screen of the output unit 49.

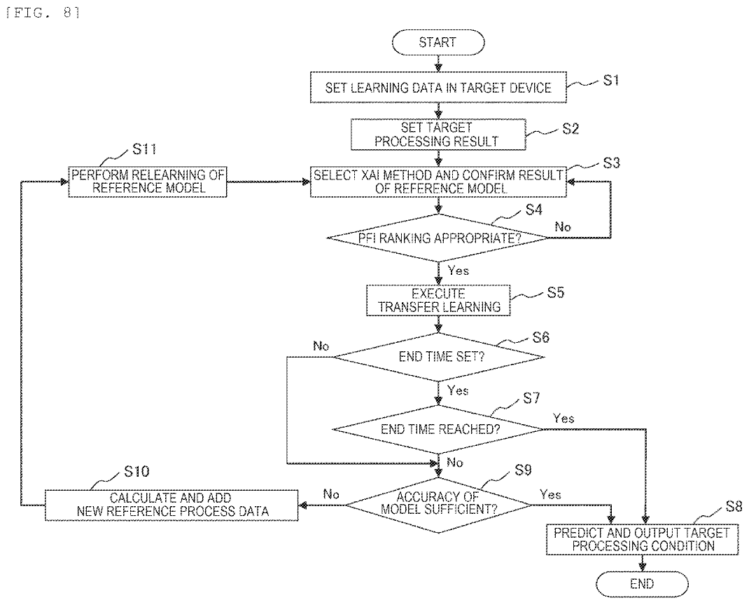

FIG. 8 is a flowchart illustrating steps S1 to S11 from start of an operation by the user to prediction of the target processing condition in Embodiment 1.

S1: Learning data that is stored in the target process database 41 and is already acquired in a target device whose target processing condition is to be predicted is set. In the transfer learning model evaluation unit 45, when it is desired to perform “test data verification” as the end determination criterion, test data is also set separately at this timing.

S2: A target processing result to be achieved by the target device is set from the target processing result setting unit 48.

S3: Features of a latest reference model created by learning based on the reference process database are confirmed in the model explanation unit 43 by several XAI methods. A model that can be confirmed at the time when the process proceeds from S2 to S3 is a reference model that learns based on any one of (1) all reference processing data, (2) reference processing data selected in advance, and (3) reference processing data selected at the time of previous use. At the time of returning from S4 to S3, learning reference processing data used for learning the reference model can be selected on a screen for creating new reference data (not shown) by clicking a “create new reference data” button 435 of the GUI 430 as shown in FIG. 6, for example. Examples of the XAI method that can confirm features of model learning data at this time include, but are not limited to, Permutation Feature Importance (PFI), Shapley Additive explanation (SHAP), Partial Dependence (PD), and Individual Conditional Expectation (ICE).

S4: Whether PFI ranking obtained in S3 is appropriate for a value set in S2 is determined. If Yes, the process proceeds to S5, and if No, the process returns to S3.

S5: Transfer learning is executed and a transfer learning model is output.

S6: In the model optimization end determination criterion setting of the transfer learning model evaluation unit of the GUI shown in FIG. 7, it is checked whether the “end time setting” has been set.

S7: If “end time setting” has been set (Yes in S6), it is determined whether the end time has been reached.

S8: If the end time has been reached (Yes in S7), the processing condition prediction unit 47 outputs a processing condition that can be expected to provide a prediction processing result closest to the target processing result. Here, a series of user operations end.

S9: If the end time has not been reached (No in S7), the transfer learning model evaluation unit 45 evaluates the accuracy of the model. In the present embodiment, since “cross verification” 4525 is set in the end determination criterion setting region 452 of the transfer learning model evaluation unit 45 of the GUI 450 shown in FIG. 7, it is determined whether a cross verification result of the model exceeds a threshold set by the user in the target processing result setting unit 48. If the accuracy equal to or higher than the threshold set by the user is obtained (Yes in S9), the process proceeds to S8, and if the accuracy is not obtained (No in S9), the process proceeds to S10.

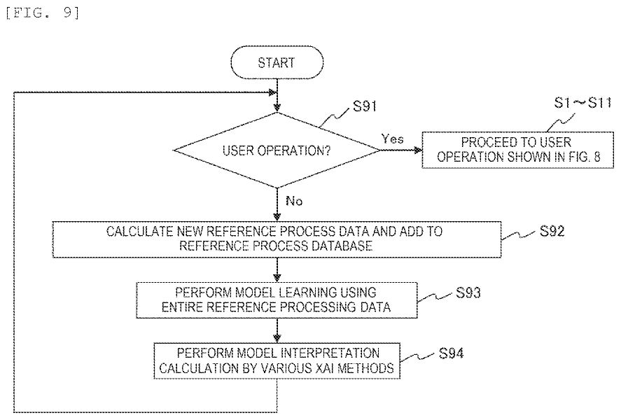

S10: The reference process data acquisition and automatic execution unit 46 calculates new reference process data according to DoE or user definition and adds the new reference process data to the reference process database 42. Here, unlike a processing flow shown in FIG. 9 to be described later, by selecting “XAI” 4523 in the end determination criterion setting region 452 of the transfer learning model evaluation unit of the GUI 450, it is possible to obtain a suggestion of a data space to be expanded by the XAI method. For example, when the PFI value of the gas A calculated by the PFI method is small even though the user knows that “the influence of the ‘gas A’ is large in the ‘etching amount’”, it is useful to obtain reference processing data in a data space in which parameters of the gas A are intensively assigned.

S11: A new learning data set to which new reference processing data is added is used, and relearning of the reference model is performed. Based on the obtained model, the process proceeds to S3 again.

As described above, in the present embodiment, the features of the model are evaluated in advance by the “model explanation unit” so as not to cause negative transfer, the model obtained as a result of the transfer learning is evaluated by the transfer learning model evaluation unit, and as a result of the model evaluation, if the evaluation value does not exceed the threshold, the simulation data of the condition necessary to increase the accuracy of the transfer learning model is automatically generated by the reference process data acquisition and automatic execution unit, and the transfer learning is performed again.

Accordingly, a transfer learning model optimum for predicting a target processing result set by a user is normally automatically constructed and updated, and it is possible to shorten and reduce a recipe optimization period for reducing a mechanical difference/component difference by utilizing a large amount of labeled data by simulation, which costs less than actual processing.

Data of tasks having different features and labels cannot be learned by a single model in machine learning of the related art using a neural net because in general, all parameters in actual processing conditions cannot be considered in physical simulation; however, according to the present invention, a search system for searching for a desired manufacturing condition of a semiconductor manufacturing apparatus by machine learning can predict a desired manufacturing condition of the semiconductor manufacturing apparatus using a model constructed by a network structure using transfer learning of data provided by a physical simulator.

### Embodiment 2

A second embodiment of the invention will be described with reference to FIG. 9.

In the present embodiment, in addition to the processing described in Embodiment 1, the processing condition search system 40 automatically performs the processing of extending the reference process database as shown in the flowchart of FIG. 9 in a period in which there is no operation of the device or method by the user as in S1 to S3 described with reference to FIG. 8 in Embodiment 1.

Procedures of the processing of extending the reference process database according to the present embodiment will be described with reference to the flowchart shown in FIG. 9.

S91: Since the operation by the user is normally prioritized, it is confirmed whether a user operation is present. That is, it is checked whether the “transfer execution” button 438 shown in FIG. 6 or the “determination” button 454 shown in FIG. 7 is pressed. If Yes (in the case where the user operation is present/expected), the process proceeds to the user operation described with reference to FIG. 8 in Embodiment 1, and the steps S1 to S11 are executed. If No, the process proceeds to S92.

S92: New reference processing data is calculated according to DoE or user definition and added to the reference process database.

S93: Each time the reference processing data is added to the database, reference model learning is performed using learning data including the newly added reference processing data, that is, model learning using the entire reference processing data is performed.

S94: Evaluation (model interpretation calculation) of the learned reference model by various XAI methods is performed. An evaluation result and the learning model are stored in the system, and the user can load the model at the timing of the processing in S3 described with reference to FIG. 8.

According to the present embodiment, in addition to the effects described in Embodiment 1, since the computer can automatically expand the reference process database in the period in which there is no operation of the device or method by the user, the accuracy of the transfer learning model can be further improved, and it is possible to further shorten the recipe optimization period for reducing the mechanical difference/component difference by utilizing a large amount of labeled data by simulation.

The invention according to Embodiments 1 and 2 may be implemented as an application mounted on a platform. The platform is constructed on a cloud, and an application that executes processing on OS and middleware operates. The user can access the platform from a terminal via the network and use a function of the application constructed on the platform. The platform includes a database and stores data necessary for executing the application. Further, the semiconductor manufacturing apparatus is connected to the platform via the network so that the data can be exchanged therebetween.

While the invention made by the inventor has been described in detail based on the embodiments, the invention is not limited to the embodiments described above, and various modifications can be made without departing from the scope of the invention. That is, the invention also includes a configuration in which a part of the configurations (steps) described in the above embodiments is replaced by a step or means having a function equivalent thereto, or a configuration in which some of the substantially not functions are omitted.

### REFERENCE SIGNS LIST

40 processing condition search system
41 target process database
42 reference process database
43 model explanation unit
44 transfer learning execution unit
45 transfer learning model evaluation unit
46 reference process data acquisition and automatic execution unit
47 processing condition prediction unit
48 target processing result setting unit
49 output unit
51 reference model
430, 450 GUI
451 reference process data acquisition and automatic execution region
450 and determination criterion setting region

1. A search apparatus that searches for a manufacturing condition corresponding to a desired processing result of a semiconductor manufacturing apparatus by predicting the manufacturing condition corresponding to the desired processing result using a learning model, the search apparatus being configured to:
generate a learning model by transfer learning using first data and second data; and
when the generated learning model does not satisfy a predetermined determination criterion, regenerate a learning model by transfer learning using the first data and the added second data.

2. The search apparatus according to claim 1, wherein
the first data includes a combination of data on a manufacturing condition of the semiconductor manufacturing apparatus and data on a processing result obtained according to the manufacturing condition of the semiconductor manufacturing apparatus, and
the second data includes data obtained by simulation.

3. The search apparatus according to claim 1, wherein
the learning model is generated based on the first data and a reference model, and
the reference model is a model generated based on an explanatory variable of the second data and an objective variable of the second data.

4. The search apparatus according to claim 3, wherein
an interpretation result of the reference model obtained by a machine learning model interpretation method including PFI or SHAP is displayed on a user interface.

5. The search apparatus according to claim 1, wherein
the first data and the second data differ in the type of explanatory variables or the number of explanatory variables, or have an inclusion relation.

6. The search apparatus according to claim 1, wherein
positions and dispersions of a data group used for the transfer learning in the second data in a data space are displayed on a user interface.

7. A semiconductor device manufacturing system, comprising:
a platform to which a semiconductor manufacturing apparatus is connected via a network and in which an application for predicting a manufacturing condition corresponding to a desired processing result of the semiconductor manufacturing apparatus using learning model is implemented, the semiconductor device manufacturing system being configured to execute, by the application,
a step of generating a learning model by transfer learning using first data and second data, and
a step of, when the generated learning model does not satisfy a predetermined determination criterion, regenerating a learning model by transfer learning using the first data and the added second data.

8. A search method for searching for a manufacturing condition corresponding to a desired processing result of a semiconductor manufacturing apparatus by predicting the manufacturing condition corresponding to the desired processing result using a learning model, the method comprising:
a step of generating a learning model by transfer learning using first data and second data; and
a step of, when the generated learning model does not satisfy a predetermined determination criterion, regenerating a learning model by transfer learning using the first data and the added second data.
